(19) United States
(12) Patent Application Publication
(10) Pub. No.: US 2023/0318320 A1
(43) Pub. Date: Oct. 5, 2023

(54) CONTROL DEVICE, COMPUTER-READABLE STORAGE MEDIUM, AND CONTROL METHOD

(71) Applicant: HONDA MOTOR CO.,LTD., Tokyo (JP)

(72) Inventors: Yuki ITO, Tokyo (JP); Akira SAITA, Tokyo (JP); Satoshi KODO, Tokyo (JP)

(21) Appl. No.: 18/190,993

(22) Filed: Mar. 28, 2023

(30) Foreign Application Priority Data
Mar. 29, 2022 (JP) 2022-054629

(51) Int. Cl. H02J 7/00

(52) U.S. Cl. CPC H02J 7/0029; H02J 7/0013; H02J 7/005

(57) ABSTRACT

A control device includes an acquisition unit for acquiring a deterioration state of each of a plurality of batteries capable of power transmission/reception between a power grid on an outside, and use information representing at least any of a use time of each of the plurality of batteries, a moving distance up to the present of a moving object comprising the plurality of batteries, and an integral power amount that is output up to the present by each of the plurality of batteries, and a selecting unit for selecting, based on a comparison result between the deterioration state and a predetermined first threshold value that is decided in accordance with the use information, a battery to be a target of the power transmission/reception from the plurality of batteries.

The contents of the following Japanese patent application(s) are incorporated herein by reference:

NO. 2022-054629 filed in JP on Mar. 29, 2022.

### TECHNICAL FIELD

The present invention relates to a control device, a computer-readable storage medium, and a control method.

### BACKGROUND

In recent years, research and development related to secondary batteries contributing to energy efficiency have been carried out such that more people can secure access to sustainable and advanced energy that is reasonable and reliable. Patent Documents 1 to 4 describe techniques related to charge and discharge of a secondary battery provided for a vehicle.

### PRIOR ART DOCUMENT

Patent Document 1: WO2013/014930.
Patent Document 2: Japanese Patent Application Publication No. 2016-77139.
Patent Document 3: Japanese Patent Application Publication No. 2011-120327.
Patent Document 4: Japanese Patent No. 6918877.

### BRIEF DESCRIPTION OF THE DRAWINGS

FIG. 1 conceptually illustrates a usage form of a system 5 in an embodiment.

FIG. 2 illustrates an example of a system configuration of a control device 100.

FIG. 3 is a graph illustrating an example of a temporal transition of a deterioration state of a battery 12.

FIG. 4 illustrates a first line 610 and a second line 620 for determining a deterioration threshold value.

FIG. 5 illustrates a case in which the battery 12 is not preferentially selected as a target of performing power transmission/reception between a power grid 90.

FIG. 6 illustrates a control mode that is set for a vehicle 10.

FIG. 7 illustrates an example of a computer 2000.

### DESCRIPTION OF EXEMPLARY EMBODIMENTS

Hereinafter, embodiments of the present invention will be described, but the following embodiments do not limit the invention according to the claims. In addition, not all of the combinations of features described in the embodiments are essential for a solving means of the invention.

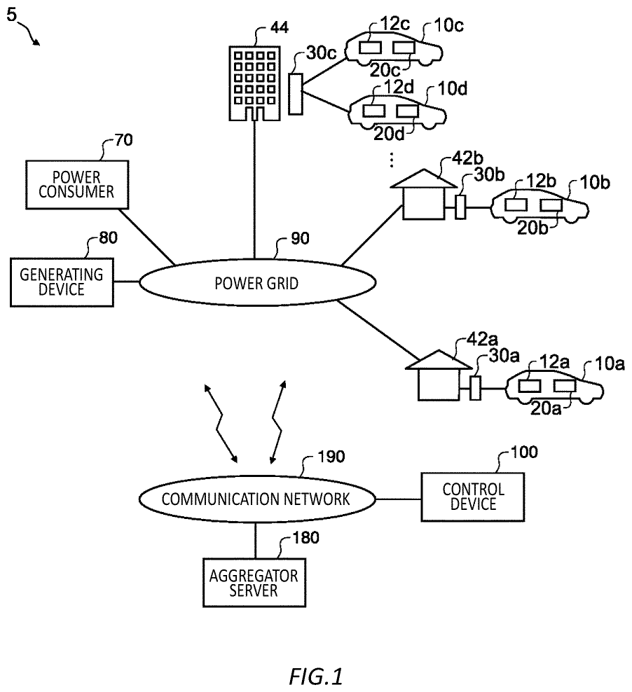

FIG. 1 conceptually illustrates a usage form of a system 5 in an embodiment. The system 5 includes a charge and discharge equipment 30a, a charge and discharge equipment 30b, a charge and discharge equipment 30c, a power generating device 80, a control device 100, an aggregator server 180, a vehicle 10a, a vehicle 10b, a vehicle 10c, and a vehicle 10d.

The vehicle 10a, the vehicle 10b, the vehicle 10c, and the vehicle 10d include a battery 12a, a battery 12b, a battery 12c, and a battery 12d, respectively. The vehicle 10a, the vehicle 10b, the vehicle 10c, and the vehicle 10d include a control device 20a, a control device 20b, a control device 20c, and a control device 20d, respectively. In the present embodiment, the vehicle 10a, the vehicle 10b, the vehicle 10c, and the vehicle 10d may be collectively referred to as the “vehicle 10”. The battery 12a, the battery 12b, the battery 12c, and the battery 12d may be collectively referred to as the “battery 12”. The control device 20a, the control device 20b, the control device 20c, and the control device 20d may be collectively referred to as the “control device 20”. The charge and discharge equipment 30a, the charge and discharge equipment 30b, and the charge and discharge equipment 30c may be collectively referred to as the “charge and discharge equipment 30”.

The control device 100 is connected to an aggregator server 180 through a communication network 190. The control device 100 can communicate with the charge and discharge equipment 30 through the communication network 190. The control device 100 controls the charge and discharge equipment 30 through the communication network 190. The control device 100 communicates with the control device 20 of the vehicle 10 through the communication network 190, and acquires various types of information of the vehicle 10 including a running history of the vehicle 10 and a SOC and a SOH of the battery 12.

The charge and discharge equipment 30, a power consumer 70, and the power generating device 80 are connected to a power grid 90. The power generating device 80 includes, for example, a power plant operated by a power company. Power generated with the power generating device 80 can be supplied to the charge and discharge equipment 30 and the power consumer 70 through the power grid 90. The power grid 90 is, for example, a power system.

Each charge and discharge equipment 30 performs charge and discharge of the battery 12 mounted on the vehicle 10 connected to each charge and discharge equipment 30. The vehicle 10 is, for example, an electric vehicle. The battery 12 is a battery for supplying power for running to the vehicle 10. The vehicle 10 may be an individually owned vehicle, a vehicle used in a business by a business operator, a shared car, or the like.

The charge and discharge equipment 30a is provided in a dwelling unit 42a, and it performs charge and discharge of the battery 12a of the vehicle 10a connected to the charge and discharge equipment 30a. If discharge of the battery 12a is performed, power provided from the battery 12a may be consumed by a power load within the dwelling unit 42a, or may be provided to the power grid 90 through a power line disposed in the dwelling unit 42a. The charge and discharge equipment 30b is provided in a dwelling unit 42b, and it performs charge and discharge of the battery 12b of the vehicle 10b connected to the charge and discharge equipment 30b. If discharge of the battery 12b is performed, power provided from the battery 12b is consumed by a power load within the dwelling unit 42b, or is provided to the power grid 90 through a power line disposed in the dwelling unit 42b. The charge and discharge equipment 30c is a charge and discharge equipment provided in a facility 44, and it performs charge and discharge of the battery 12c and the battery 12d mounted on the vehicle 10c and the vehicle 10d connected to the charge and discharge equipment 30c. If discharge of the battery 12c and the battery 12d is performed, power provided from the battery 12c and the battery 12d may be consumed by a power load within the facility 44, or may be provided to the power grid 90 through a power line disposed in the facility 44.

Each charge and discharge equipment 30 can charge the battery 12 with power received from the power grid 90. The charge and discharge equipment 30 can transmit power to the power grid 90 by discharging the battery 12.

When performing power transmission/reception between the power grid 90 and the battery 12, the charge and discharge equipment 30 and the control device 20 of the vehicle 10 perform charge and discharge of the battery 12 in accordance with a control of the control device 100. For example, if power shortage occurs in the power grid 90, the control device 100 can perform power transmission from the battery 12 to the power grid 90 by instructing the charge and discharge equipment 30 and the control device 20 to discharge the battery 12. If an excess of power occurs in the power grid 90, the control device 100 can reduce the excess of power of the power grid 90 by instructing the charge and discharge equipment 30 and the control device 20 to charge the battery. In this manner, the control device 100 can provide a primary adjusting force, a secondary adjusting force, a tertiary adjusting force, and the like in the power grid 90 in conjunction with the charge and discharge equipment 30 and the control device 20. By doing so, the control device 100 can aggregate a plurality of the batteries 12 mounted on a plurality of the vehicles 10, and can provide a power resource for the power grid 90.

The aggregator server 180 is, for example, a server used by a power aggregator. The aggregator server 180 performs a power transaction in a power market. The control device 100 communicates with the aggregator server 180, and provides power of a required amount to the power grid 90. For example, the control device 100 controls the charge and discharge equipment 30 and the control device 20 to charge and discharge the battery 12 in accordance with a demand from the aggregator server 180, and provides power of an amount in accordance with the demand.

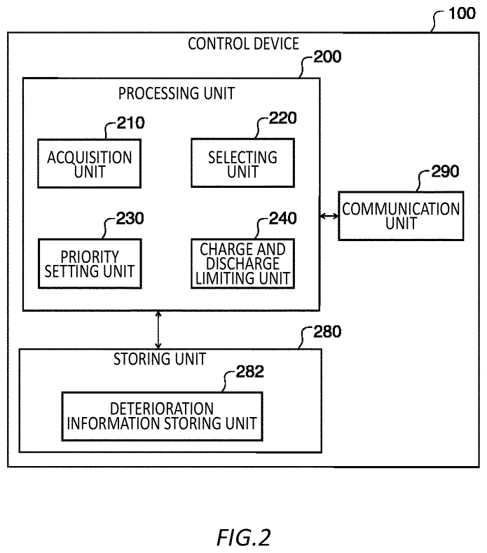

FIG. 2 illustrates an example of a system configuration of the control device 100. The control device 100 includes a processing unit 200, a storing unit 280, and a communication unit 290.

The processing unit 200 performs a control of the communication unit 290. The communication unit 290 carries out communication between the aggregator server 180 and the vehicle 10. The processing unit 200 is achieved by an arithmetic processing device including a processor. The storing unit 280 is achieved by a non-volatile storage medium respectively included. The processing unit 200 performs processing by using information stored in the storing unit 280. The processing unit 200 may be achieved by a microcomputer including a CPU, a ROM, a RAM, an I/O, a bus, or the like. The control device 100 may be achieved by a computer.

In the present embodiment, the control device 100 is achieved by a single computer. However, in another embodiment, the control device 100 may be achieved by a plurality of computers. At least a part of functions of the control device 100 may be achieved by one or more servers such as a cloud server.

The processing unit 200 includes an acquisition unit 210, a selecting unit 220, a priority setting unit 230, and a charge and discharge limiting unit 240. The storing unit 280 includes a deterioration information storing unit 282.

The acquisition unit 210 acquires a deterioration state of each of the plurality of batteries 12 capable of power transmission/reception between the power grid 90 on an outside, and use information representing at least any of a use time of each of the plurality of batteries 12, a moving distance up to the present of the vehicle 10 including the plurality of batteries 12, and an integral power amount that is output up to the present by each of the plurality of batteries 12. The selecting unit 220 selects, based on a comparison result between the deterioration state and a predetermined first threshold value that is decided in accordance with the use information, the battery 12 to be the target of power transmission/reception from the plurality of batteries 12.

The use information may include at least a use time. If the deterioration state indicates lowness of deterioration of each of the plurality of batteries 12, the first threshold value may take a lower value as the use time becomes longer.

The use information may include at least a moving distance. If the deterioration state indicates lowness of deterioration of each of the plurality of batteries 12, the first threshold value may take a lower value as the moving distance becomes longer.

The use information may include at least an integral power amount. If the deterioration state indicates lowness of deterioration of each of the plurality of batteries 12, the first threshold value takes a lower value as the integral power amount becomes larger.

The selecting unit 220 may select, among the plurality of batteries 12, the battery 12 in which the deterioration state is equal to or higher than the first threshold value as the target of power transmission/reception, in priority to the battery 12 in which the deterioration state is lower than the first threshold value.

The priority setting unit 230 may set a priority for each of the plurality of batteries 12 to be selected as the battery 12 for performing power transmission/reception. If the deterioration state indicates lowness of deterioration of each of the plurality of batteries 12, the first threshold value takes a lower value as the priority becomes higher.

The use information may include at least a use time. The deterioration information storing unit 282 stores therein first deterioration information representing a variation in the first threshold value with respect to a variation in the use time, and second deterioration information in which the variation in the first threshold value with respect to the variation in the use time is smaller than the first deterioration information. The selecting unit 220 selects, for each of the plurality of batteries 12, either of the first deterioration information and the second deterioration information in accordance with the priority, and calculates the first threshold value by using the selected deterioration information.

If the deterioration state indicates lowness of deterioration of each of the plurality of batteries 12, the charge and discharge limiting unit 240 limits at least either of charge and discharge power and an amount of charge and discharge power of the battery 12 in which the deterioration state is lower than a second threshold value, among the plurality of batteries 12.

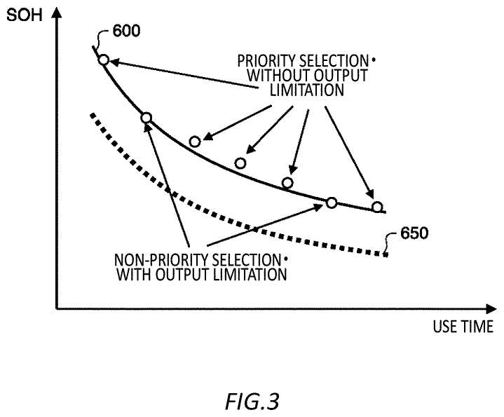

FIG. 3 is a graph illustrating an example of a temporal transition of the deterioration state of the battery 12. The horizontal axis of the graph in FIG. 3 is the use time of the vehicle 10, and the vertical axis is the SOH (State of health).

The SOH is an example of the deterioration state of the battery 12. The SOH is also referred to as the state of health. The SOH may be expressed by a capacity maintenance rate or an increase rate of internal resistance. In the present embodiment, the SOH is expressed by, for example, the capacity maintenance rate, and it indicates lowness of deterioration of the battery 12. The use time is, for example, an elapsed time from the start of use of the vehicle 10. Due to the use of the battery 12 in accordance with the use of the vehicle 10, the SOH of the battery 12 may be lowered.

A reference line 600 indicates a deterioration threshold value that varies depending on the use time of the vehicle 10. The deterioration threshold value is the first threshold value, which is the judgmental standard of whether to preferentially select the battery 12 as the battery for performing power transmission/reception between the power grid 90. The deterioration threshold value may be the second threshold value, which is the judgmental standard of judging whether to limit the power or the power amount to be transmitted/received between the battery 12 and the power grid 90. As indicated by the reference line 600, the deterioration threshold value takes a lower value as the use time becomes longer. The reference deterioration information representing the reference line 600 is stored in the deterioration information storing unit 282. The reference deterioration information may be a conversion table for converting a use time into a deterioration threshold value.

A lower limit line 650 indicates a SOH lower limit value that varies depending on the use time of the vehicle 10. The SOH lower limit value is the lowest value allowed for lowering of the SOH of the battery 12. The reference line 600 is set higher than the lower limit line 650. For example, the reference line 600 may be set based on a detection error of the SOH from the lower limit line 650.

The selecting unit 220 determines the deterioration threshold value from the use time of the vehicle 10 by referring to the reference deterioration information representing the reference line 600, for each of the batteries 12 included in the vehicle 10. The selecting unit 220 preferentially selects, for each of the batteries 12, the battery 12 in which the SOH is equal to or higher than the deterioration threshold value as the battery 12 for performing power transmission/reception between the power grid 90. The selecting unit 220 does not select the battery 12 in which the SOH is equal to or lower than the lower limit line 650, as the battery 12 for performing power transmission/reception between the power grid 90.

The charge and discharge limiting unit 240 controls charge and discharge of at least a part of the battery 12 selected by the selecting unit 220, and provides power that is required to be passed between the power grid 90 from the battery 12. If the battery 12 in which the SOH is equal to or higher than the deterioration threshold value is caused to transmit/receive power between the power grid 90, the charge and discharge limiting unit 240 does not have to limit the transmitted/received power or the amount of transmitted/received power of the battery 12 between the power grid 90. On the other hand, if the battery 12 in which the SOH is lower than the deterioration threshold value is caused to transmit/receive power between the power grid 90, the charge and discharge limiting unit 240 may limit the transmitted/received power or the amount of transmitted/received power of the battery 12 between the power grid 90 to a predetermined value or less.

In this manner, the battery 12 in which the SOH is equal to or higher than the deterioration threshold value decided from the use time of the vehicle 10 can be preferentially caused to transmit/receive power between the power grid 90. By doing so, the battery 12 in which the SOH is higher with respect to the deterioration threshold value decided from the use time can be effectively used for power transmission/reception between the power grid 90. In addition, the battery 12 in which the SOH is lower with respect to the deterioration threshold value decided from the use time can be made less likely to be selected for power transmission/reception between the power grid 90. Therefore, it is possible to prevent the period of use of the vehicle 10 from ending in a state that the SOH of the battery 12 is extremely high. In addition, it is possible to prevent the life of the battery 12 from being exhausted before the end of the period of use of the vehicle 10.

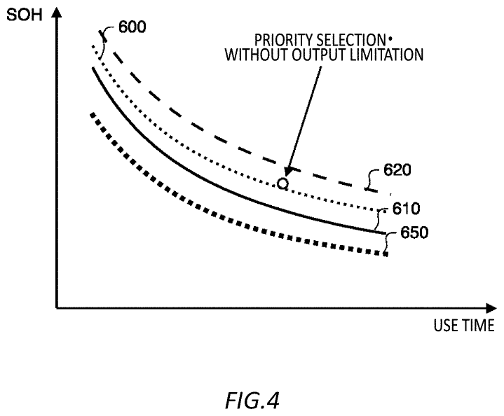

FIG. 4 illustrates a first line 610 and a second line 620 for determining the deterioration threshold value. The first line 610 is used when preferentially selecting the battery 12 as the target of performing power transmission/reception between the power grid 90. The second line 620 is used when not preferentially selecting the battery 12 as the target of performing power transmission/reception between of the power grid 90. Whether to preferentially select as the target of performing power transmission/reception between the power grid 90 may be set by, for example, a user of the vehicle 10.

The first line 610 is set lower than the second line 620. Accordingly, a variation in the deterioration threshold value with respect to a variation in the use time of the second line 620 is gradual as compared to the first line 610. The first deterioration information representing the first line 610 and the second deterioration information representing the second line 620 are stored in the deterioration information storing unit 282. The first deterioration information and the second deterioration information may be a conversion table for converting a use time into a deterioration threshold value.

The selecting unit 220 calculates the deterioration threshold value by using the first deterioration information, for the battery 12 preferentially selected as the target of performing power transmission/reception between the power grid 90. The selecting unit 220 calculates the deterioration threshold value by using the second deterioration information, for the battery 12 not preferentially selected as the target of performing power transmission/reception between the power grid 90. FIG. 4 illustrates a case in which the battery 12 is preferentially selected as the target of performing power transmission/reception between the power grid 90. As illustrated in FIG. 4, since the SOH is equal to or higher than the deterioration threshold value calculated from the use time and the first deterioration information, the selecting unit 220 makes a further preferential selection as the battery 12 for performing power transmission/reception between the power grid 90.

If the battery 12 is caused to transmit/receive power between the power grid 90, the charge and discharge limiting unit 240 controls, based on the reference line 600 and the SOH, whether to limit the transmitted/received power or the amount of transmitted/received power of the battery 12 between the power grid 90. For example, as illustrated in FIG. 4, if the SOH is equal to or higher than the deterioration threshold value decided from the reference line 600, the charge and discharge limiting unit 240 does not limit the transmitted/received power or the amount of transmitted/received power of the battery 12. On the other hand, if the SOH is lower than the deterioration threshold value decided from the reference line 600, the charge and discharge limiting unit 240 may limit the transmitted/received power or the amount of transmitted/received power of the battery 12 between the power grid 90.

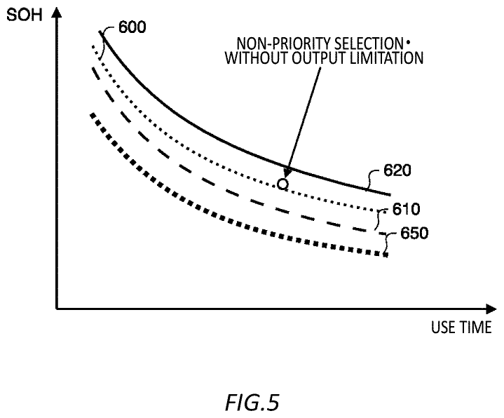

FIG. 5 illustrates a case in which the battery 12 is not preferentially selected as the target of performing power transmission/reception between the power grid 90. In this case, the deterioration threshold value is calculated from the second deterioration information.

In the example of FIG. 5, since the SOH of the battery 12 is lower than the deterioration threshold value calculated from the use time and the second deterioration information, the selecting unit 220 does not make a preferential selection as the battery 12 for performing power transmission/reception between the power grid 90.

For example, on the condition that a power amount required to be passed between the power grid 90 cannot be provided from the battery 12 in which the SOH is equal to or higher than the deterioration threshold value calculated from the first deterioration information, the selecting unit 220 selects the battery 12 in which the SOH is lower than the deterioration threshold value calculated from the second deterioration information as the target of performing power transmission/reception between the power grid 90, and if the power amount required to be passed between the power grid 90 can be provided from the battery 12 in which the SOH is equal to or higher than the deterioration threshold value calculated from the first deterioration information, the selecting unit 220 does not select the battery 12 in which the SOH is lower than the deterioration threshold value calculated from the second deterioration information as the target of performing power transmission/reception between the power grid 90.

If the battery 12 is caused to transmit/receive power between the power grid 90, the charge and discharge limiting unit 240 controls, based on the reference line 600 and the SOH, whether to limit the transmitted/received power or the amount of transmitted/received power of the battery 12 between the power grid 90. As described in connection to FIG. 4, if the SOH is equal to or higher than the deterioration threshold value decided from the reference line 600, the charge and discharge limiting unit 240 does not limit the transmitted/received power or the amount of transmitted/received power of the battery 12 between the power grid 90. On the other hand, if the SOH is lower than the deterioration threshold value decided from the reference line 600, the charge and discharge limiting unit 240 may limit the transmitted/received power or the amount of transmitted/received power of the battery 12 between the power grid 90. It should be noted that, when setting the second line 620 higher than the reference line 600, if the SOH is lower than the deterioration threshold value decided from the second line 620, the charge and discharge limiting unit 240 may limit the transmitted/received power or the amount of transmitted/received power of the battery 12 between the power grid 90.

It should be noted that, the reference line 600, the first line 610, and the second line 620 described above are merely examples for determining the deterioration threshold value in accordance with the use time. The relationship between the reference line 600, and the first line 610 and the second line 620 may be arbitrarily set. Either of the first line 610 and the second line 620 may match the reference line 600.

In connection to FIG. 3 to FIG. 5 and the like, descriptions have been made on the control in which the reference line 600, the lower limit line 650, the first line 610, and the second line 620 are decided using the use time of the vehicle 10 as the parameter, and based on a comparison result between the value of the reference line 600, the lower limit line 650, the first line 610, or the second line 620 corresponding to the use time of the vehicle 10 at the present and the SOH at the present, the vehicle 10 to be the target of power transmission/reception between the power grid 90 is selected. The use time of the vehicle 10 is an example of use information of the battery 12. As the use information of the battery 12, one or any combination of the use time of the vehicle 10, the moving distance up to the present of the vehicle 10, and the integral power amount output up to the present by each battery 12, can be applied. For example, a conversion table defining each value of the deterioration threshold value indicated by the reference line, the SOH lower limit value indicated by the lower limit line, the deterioration threshold value indicated by the first line, and the deterioration threshold value indicated by the second line using one or any combination of the use time, the moving distance, and the integral power amount as the parameter is prepared in advance, and the selecting unit 220 may use the conversion table to compare one or any combination of the use time, the moving distance, and the integral power amount with the SOH of the vehicle 10 at the present by converting one or more of the use time at the present, the moving distance at the present, and the integral power amount at the present into the deterioration threshold value indicated by the reference line, the SOH lower limit value indicated by the lower limit line, the deterioration threshold value indicated by the first line, and the deterioration threshold value indicated by the second line, and may select the vehicle 10 to be the target of power transmission/reception between the power grid 90.

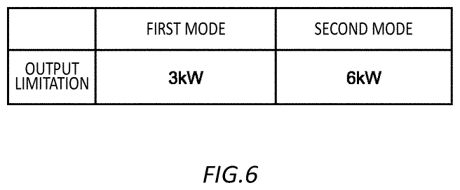

FIG. 6 illustrates a control mode that is set for the vehicle 10. The control mode includes a first mode and a second mode. The first mode is a control mode when limiting transmitted/received power between the power grid 90 and the battery 12. The second mode is a control mode when transmitted/received power between the power grid 90 and the battery 12 is less limited than when the first mode is set.

With regard to the vehicle 10 in which the first mode is set, the charge and discharge limiting unit 240 limits the upper limit value of transmitted/received power between the power grid 90 and the battery 12 to 3 kW. With regard to the vehicle 10 in which the second mode is set, the charge and discharge limiting unit 240 limits the upper limit value of transmitted/received power between the power grid 90 and the battery 12 to 6 kW at a maximum. It should be noted that the output limit value 3 kW defined for the first mode and the output limit value 6 kW defined for the second mode illustrated in FIG. 6 are examples of limited power of transmitted/received power of the battery 12. For example, with regard to the first mode, power that allows a deterioration influence on the battery 12 to be equivalent to calendar deterioration can be defined as the output limit value. For example, with regard to the second mode, a maximum output of the charge and discharge equipment 30 or a maximum output or the like of the vehicle 10 at the time of charge and discharge can be defined as the output limit value.

In the vehicle 10 in which the control mode is set to the second mode, if the SOH of the battery 12 is equal to or higher than the deterioration threshold value described above, the charge and discharge limiting unit 240 sets the upper limit value of transmitted/received power between the power grid 90 and the battery 12 to 6 kW, which is defined in the second mode. If the SOH of the battery 12 is equal to or lower than the deterioration threshold value described above, the charge and discharge limiting unit 240 switches the control mode of the vehicle 10 to the first mode, and limits transmitted/received power between the power grid 90 and the battery 12 to 3 kW, which is defined in the first mode, or less. By doing so, deterioration of the battery 12 can be suppressed. By making the output power of the battery 12 small, lowering of the SOH may be very little. Therefore, depending on the type of the battery 12, by limiting the output power of the battery 12 to power about, for example, 3 kW, lowering of a deterioration level of the battery 12 can be suppressed even if the battery 12 is used for power transmission/reception between the power grid 90. By performing the control in this manner, the SOH can be brought closer to the reference line 600 with a passage of time, while using the battery 12 for power transmission/reception between the power grid 90.

It should be noted that, although FIG. 6 exemplified the case in which the output power is limited as a technique of performing output limitation, a technique of limiting the amount of output power can also be applied. Besides, as the technique of performing output limitation, a technique of performing limitation of the output power and limitation of the amount of output power can also be applied.

In the present embodiment, the battery 12 is a battery provided for the vehicle 10. In another embodiment, the battery 12 may be a battery not provided for the vehicle 10. For example, the battery 12 may be a fixed battery.

The vehicle 10 may be electric-powered vehicles including an electric vehicle, a hybrid automobile, and a saddle-type vehicle such as an electric-powered motorcycle. The vehicle 10 is an example of the moving object. The moving object may be any moving object including a battery that moves on land other than vehicles. The moving object may include an aircraft such as an unmanned aerial vehicle (UAV), a marine vessel, and the like.

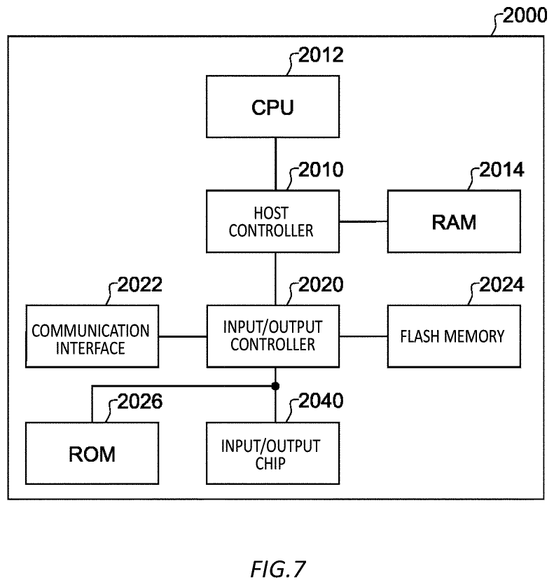

FIG. 7 illustrates an example of a computer 2000 in which a plurality of embodiments of the present invention may be entirely or partially embodied. A program installed in the computer 2000 can cause the computer 2000 to function as a system according to an embodiment or each unit of the system, or a device such as the control device 20 or each unit of the device, execute an operation associated with the system or each unit of the system, or the device or each unit of the device, and/or execute a process according to the embodiment or a step of the process. Such a program may be executed by a CPU 2012 to cause the computer 2000 to perform certain operations associated with the processing procedures described herein and some of or all of the blocks in the block diagrams.

The computer 2000 according to the present embodiment includes the CPU 2012 and a RAM 2014, which are mutually connected by a host controller 2010. The computer 2000 also includes a ROM 2026, a flash memory 2024, a communication interface 2022, and an input/output chip 2040. The ROM 2026, the flash memory 2024, the communication interface 2022, and the input/output chip 2040 are connected to the host controller 2010 via an input/output controller 2020.

The CPU 2012 operates according to programs stored in the ROM 2026 and the RAM 2014, thereby controlling each unit.

The communication interface 2022 communicates with other electronic devices via a network. The flash memory 2024 stores programs and data used by the CPU 2012 within the computer 2000. The ROM 2026 stores therein a boot program or the like executed by the computer 2000 at the time of activation, and/or a program depending on the hardware of the computer 2000. The input/output chip 2040 may connect various input/output units such as a keyboard, a mouse, and a monitor to the input/output controller 2020 via input/output ports such as a serial port, a parallel port, a keyboard port, a mouse port, a monitor port, a USB port, and a HDMI (registered trademark) port.

A program is provided via a network or computer-readable storage medium such as a CD-ROM, a DVD-ROM, or a memory card. The RAM 2014, the ROM 2026, or the flash memory 2024 is an example of the computer-readable storage medium. Programs are installed in the flash memory 2024, the RAM 2014, or the ROM 2026 and executed by the CPU 2012. The information processing written in these programs is read by the computer 2000, and thereby cooperation between a program and the above-described various types of hardware resources is achieved. A device or method may be constituted by carrying out the operation or processing of information by using the computer 2000.

For example, when communication is carried out between the computer 2000 and an external device, the CPU 2012 may execute a communication program loaded onto the RAM 2014 to instruct communication processing to the communication interface 2022, based on the processing written in the communication program. The communication interface 2022, under the control of the CPU 2012, reads transmission data stored on transmission buffering regions provided in recording media such as the RAM 2014 and the flash memory 2024, and transmits the read transmission data to a network and writes reception data received from a network to reception buffering regions or the like provided on the recording media.

In addition, the CPU 2012 may cause all or a necessary portion of a file or a database to be read into the RAM 2014, the file or the database having been stored in a recording medium such as the flash memory 2024, etc., and perform various types of processing on the data on the RAM 2014. The CPU 2012 may then write back the processed data to the recording medium.

Various types of information, such as various types of programs, data, tables, and databases, may be stored in the recording medium to undergo information processing. The CPU 2012 may perform various types of processing on the data read from the RAM 2014, which includes various types of operations, information processing, conditional judging, conditional branch, unconditional branch, search/replacement of information, etc., as described herein and designated by an instruction sequence of programs, and writes the result back to the RAM 2014. In addition, the CPU 2012 may search for information in a file, a database, etc., in the recording medium. For example, when a plurality of entries, each having an attribute value of a first attribute associated with an attribute value of a second attribute, are stored in the recording medium, the CPU 2012 may search for an entry matching the condition whose attribute value of the first attribute is designated, from among the plurality of entries, and read the attribute value of the second attribute stored in the entry, thereby acquiring the attribute value of the second attribute associated with the first attribute satisfying the predetermined condition.

The programs or software modules described above may be stored in the computer-readable storage medium on the computer 2000 or in the vicinity of the computer 2000. A recording medium such as a hard disk or a RAM provided in a server system connected to a dedicated communication network or the Internet can be used as the computer-readable storage media. A program stored in the computer-readable storage medium may be provided to the computer 2000 via a network.

The program installed in the computer 2000 and causing the computer 2000 to function as the control device 100 may instruct the CPU 2012 or the like to cause the computer 2000 to respectively function as each unit of the control device 100. Information processing written in these programs is read in the computer 2000 to function as each unit of the control device 100, which is a specific means in which a software and various hardware resources described above are in cooperation. Then, these specific means implement operations or processing of information according to the intended use of the computer 2000 in the present embodiment, so that the control device 100 is constructed as a specific device according to the intended use.

Various embodiments have been described by referring to the block diagrams and the like. In the block diagram, each block may represent (1) a step of a process in which an operation is executed, or (2) each unit of the device having a role of executing the operation. Certain steps and each unit may be implemented by dedicated circuits, programmable circuits supplied with computer-readable instructions stored on computer-readable storage media, and/or processors supplied with computer-readable instructions stored on computer-readable storage media. Dedicated circuits may include digital and/or analog hardware circuits and may include integrated circuits (IC) and/or discrete circuits. Programmable circuits may include reconfigurable hardware circuits including logical AND, logical OR, logical XOR, logical NAND, logical NOR, and other logical operations, flip-flops, registers, memory elements, etc., such as field-programmable gate arrays (FPGA), programmable logic arrays (PLA), etc.

Computer-readable storage media may include any tangible device that can store instructions for execution by a suitable device, such that the computer-readable storage medium having instructions stored therein forms at least a portion of an article of manufacture including instructions which can be executed to create means for performing processing procedure or operations specified in the block diagrams. Examples of the computer-readable storage medium may include an electronic storage medium, a magnetic storage medium, an optical storage medium, an electromagnetic storage medium, a semiconductor storage medium, and the like. More specific examples of the computer-readable storage medium may include a floppy (registered trademark) disk, a diskette, a hard disk, a random access memory (RAM), a read only memory (ROM), an erasable programmable read only memory (EPROM or flash memory), an electrically erasable programmable read only memory (EEPROM), a static random access memory (SRAM), a compact disk read only memory (CD-ROM), a digital versatile disk (DVD), a Blu-ray (registered trademark) disk, a memory stick, an integrated circuit card, or the like.

The computer-readable instruction may include an assembler instruction, an instruction-set-architecture (ISA) instruction, a machine instruction, a machine dependent instruction, a microcode, a firmware instruction, state-setting data, or either of source code or object code written in any combination of one or more programming languages including an object-oriented programming language such as Smalltalk (registered trademark), JAVA (registered trademark), and C++, and a conventional procedural programming language such as a “C” programming language or a similar programming language.

Computer-readable instructions may be provided to a processor of a general purpose computer, special purpose computer, or other programmable data processing device, or to programmable circuit, locally or via a local area network (LAN), wide area network (WAN) such as the Internet, etc., to execute the computer-readable instructions to provide means for performing described processing procedure or operations specified in the block diagrams. Examples of the processor include a computer processor, a processing unit, a microprocessor, a digital signal processor, a controller, a microcontroller, and the like.

While the present invention has been described with the embodiments, the technical scope of the present invention is not limited to the above-described embodiments. It is apparent to persons skilled in the art that various alterations or improvements can be added to the above-described embodiments. It is also apparent from the description of the claims that the embodiments to which such alterations or improvements are made can be included in the technical scope of the present invention.

The operations, procedures, steps, stages, and the like of each process performed by a device, system, program, and method shown in the claims, specification, or drawings can be performed in any order as long as the order is not indicated by “prior to,” “before,” or the like and as long as the output from a previous process is not used in a later process. Even if the operation flow is described using phrases such as “first” or “next” in the claims, specification, or drawings, it does not necessarily mean that the process must be performed in this order.

### EXPLANATION OF REFERENCES

5: system; 10: vehicle; 12: battery; 20: control device; 30: charge and discharge equipment; 42: dwelling unit; 44: facility; 70: power consumer; 80: power generating device; 90: power grid; 100: control device; 180: aggregator server; 190: communication network; 200: processing unit; 210: acquisition unit; 220: selecting unit; 230: priority setting unit; 240: charge and discharge limiting unit; 282: deterioration information storing unit; 280: storing unit; 290: communication unit; 600: reference line; 610: first line; 620: second line; 650: lower limit line; 2000: computer; 2010: host controller; 2012: CPU; 2014: RAM; 2020: input/output controller; 2022: communication interface; 2024: flash memory; 2026: ROM; 2040: input/output chip.

What is claimed is:

1. A control device, comprising:
an acquisition unit for acquiring a deterioration state of each of a plurality of batteries capable of power transmission/reception between a power grid on an outside, and use information representing at least any of a use time of each of the plurality of batteries, a moving distance up to the present of a moving object comprising the plurality of batteries, and an integral power amount that is output up to the present by each of the plurality of batteries; and
a selecting unit for selecting, based on a comparison result between the deterioration state and a predetermined first threshold value that is decided in accordance with the use information, a battery to be a target of the power transmission/reception from the plurality of batteries.

2. The control device according to claim 1, wherein
the use information comprises at least the use time,
the deterioration state indicates lowness of deterioration of each of the plurality of batteries, and
the first threshold value takes a lower value as the use time becomes longer.

3. The control device according to claim 1, wherein
the use information comprises at least the moving distance,
the deterioration state indicates lowness of deteriorate of each of the plurality of batteries, and
the first threshold value takes a lower value as the moving distance becomes longer.

4. The control device according to claim 1, wherein
the use information comprises at least the integral power amount,
the deterioration state indicates lowness of deterioration of each of the plurality of batteries, and
the first threshold value takes a lower value as the integral power amount becomes larger.

5. The control device according to claim 2, wherein the selecting unit selects, among the plurality of batteries, a battery in which the deterioration state is equal to or higher than the first threshold value as a target of the power transmission/reception in priority to a battery in which the deterioration state is lower than the first threshold value.

6. The control device according to claim 1, further comprising a priority setting unit for setting a priority for each of the plurality of batteries to be selected as a battery for performing the power transmission/reception, wherein
the deterioration state indicates lowness of deterioration of each of the plurality of batteries, and
the first threshold value takes a lower value as the priority becomes higher.

7. The control device according to claim 6, further comprising a deterioration information storing unit for storing therein first deterioration information representing a variation in the first threshold value with respect to a variation in the use time and second deterioration information in which a variation in the first threshold value with respect to a variation in the use time is smaller than the first deterioration information, wherein
the use information comprises at least the use time, and
the selecting unit selects, for each of the plurality of batteries, either of the first deterioration information and the second deterioration information in accordance with the priority, and calculates the first threshold value by using the selected deterioration information.

8. The control device according to claim 1, further comprising a charge and discharge limiting unit for limiting at least either of charge and discharge power and an amount of charge and discharge power of, among the plurality of batteries, a battery in which the deterioration state is lower than a second threshold value, wherein
the deterioration state indicates lowness of deterioration of each of the plurality of batteries.

9. The control device according to claim 1, wherein the plurality of batteries are batteries mounted on a plurality of vehicles that are different from one another.

10. The control device according to claim 2, wherein
the use information comprises at least the moving distance,
the deterioration state indicates lowness of deterioration of each of the plurality of batteries, and
the first threshold value takes a lower value as the moving distance becomes longer.

11. The control device according to claim 2, wherein
the use information comprises at least the integral power amount,
the deterioration state indicates lowness of deterioration of each of the plurality of batteries, and
the first threshold value takes a lower value as the integral power amount becomes larger.

12. The control device according to claim 3, wherein
the use information comprises at least the integral power amount,
the deterioration state indicates lowness of deterioration of each of the plurality of batteries, and
the first threshold value takes a lower value as the integral power amount becomes larger.

13. The control device according to claim 10, wherein
the use information comprises at least the integral power amount,
the deterioration state indicates lowness of deterioration of each of the plurality of batteries, and
the first threshold value takes a lower value as the integral power amount becomes larger.

14. The control device according to claim 3, wherein the selecting unit selects, among the plurality of batteries, a battery in which the deterioration state is equal to or higher than the first threshold value as a target of the power transmission/reception in priority to a battery in which the deterioration state is lower than the first threshold value.

15. The control device according to claim 4, wherein the selecting unit selects, among the plurality of batteries, a battery in which the deterioration state is equal to or higher than the first threshold value as a target of the power transmission/reception in priority to a battery in which the deterioration state is lower than the first threshold value.

16. The control device according to claim 2, further comprising a priority setting unit for setting a priority for each of the plurality of batteries to be selected as a battery for performing the power transmission/reception, wherein
the deterioration state indicates lowness of deterioration of each of the plurality of batteries, and
the first threshold value takes a lower value as the priority becomes higher.

17. The control device according to claim 3, further comprising a priority setting unit for setting a priority for each of the plurality of batteries to be selected as a battery for performing the power transmission/reception, wherein
the deterioration state indicates lowness of deterioration of each of the plurality of batteries, and
the first threshold value takes a lower value as the priority becomes higher.

18. The control device according to claim 4 further comprising a priority setting unit for setting a priority for each of the plurality of batteries to be selected as a battery for performing the power transmission/reception, wherein
the deterioration state indicates lowness of deterioration of each of the plurality of batteries, and
the first threshold value takes a lower value as the priority becomes higher.

19. A non-transitory computer-readable storage medium having stored therein a program for causing a computer to function as
an acquisition unit for acquiring a deterioration state of each of a plurality of batteries capable of power transmission/reception between a power grid on an outside, and use information representing at least any of a use time of each of the plurality of batteries, a moving distance up to the present of a moving object comprising the plurality of batteries, and an integral power amount that is output up to the present by each of the plurality of batteries, and
a selecting unit for selecting, based on a comparison result between the deterioration state and a predetermined first threshold value that is decided in accordance with the use information, a battery to be a target of the power transmission/reception from the plurality of batteries.

20. A control method, comprising:
acquiring a deterioration state of each of a plurality of batteries capable of power transmission/reception between a power grid on an outside, and use information representing at least any of a use time of each of the plurality of batteries, a moving distance up to the present of a moving object comprising the plurality of batteries, and an integral power amount that is output up to the present by each of the plurality of batteries; and
selecting, based on a comparison result between the deterioration state and a predetermined first threshold value that varies with respect to the use information, a battery to be a target of the power transmission/reception from the plurality of batteries.
